(19) United States
(12) Patent Application Publication
(10) Pub. No.: US 2005/0069153 A1
(43) Pub. Date: Mar. 31, 2005

(54) Adjustable speaker systems and methods

(76) Inventors: David S. Hall, Los Altos Hill, CA (US); Bruce H. Hall, Palo Alto, CA (US)

Correspondence Address: Michael S. Smith;BLACK LOWE & GRAHAM PLLC, Suite 4800, 701 Fifth Avenue, Seattle, WA, 98104, US

(21) Appl. No.: 10/672,841

(22) Filed: Sep. 26, 2003

(51) Int. Cl. H03G 5/00; H04R 29/00

(52) U.S. Cl. 381/103; 381/56

(57) ABSTRACT

Systems and methods for optimizing speaker performance. The system includes a self-contained speaker unit that includes a speaker, an amplifier coupled to the speaker, and a processor coupled to the amplifier. The processor receives a first sound signal from a receiver and a second sound signal from a microphone, processes the first sound signal based on a plurality of parameters, outputs the processed sound signal to the speaker, and generates a video signal based on the second sound signal. A wireless remote control allows a user to manipulate the parameters. The processor generates a test sound signal and outputs it to the receiver. The receiver processes the test sound signal and returns it to the processor for output through the speaker. The video signal includes a graphical user interface having a frequency response graph of the second sound signal and an eight band equalizer.

### FIELD OF THE INVENTION

This invention relates generally to speakers and, more specifically, to systems and methods for optimal speaker adjustment.

### BACKGROUND OF THE INVENTION

Producing high quality sound in a home speaker system is a challenging task, particularly because of the endless variety of possible orientations and interactions the speaker might have with respect to a listener. A single speaker might sound great in one location in a room, but sound much worse in different speaker locations or in different listening locations with respect to a static speaker location. A subwoofer might sound very good with one set of main speakers, but not sound good at all with another set, due to differences in frequency response between the speakers. Some music entertainment systems have employed a number of methods in an effort to improve sound quality and compensate for less than ideal speaker or listening locations, and for alternate speaker settings and/or performance. One method uses external equipment for measurement and correction. Some subwoofers include equalizer filters with externally generated test tones. The subwoofers rely on the user to chart results obtained external to the subwoofer either on a paper graph or using computer software. The user sets dials or other controls on the subwoofer to accomplish the equalization as indicated via the written instruction or instructions presented in a software application program.

Infinity's Room Adaptive Bass Optimization System (RABOS) employed in Infinity subwoofers such as the PRELUDE MTS, uses a single-band parametric equalizer. RABOS includes an SPL meter, a test CD, and blank graph paper. While playing tones on the CD the user manually graphs the response in the room then sets an equalizer, which contains controls for frequency, level, and width (Q).

The REVEL PERFORMA B15 subwoofer system features a built-in 3-band parametric equalizer. Downloadable software, entitled Revel Low Frequency Optimizer (LFO), allows a user to enter room measurements using a sound pressure meter microphone or other input device, and then perform an analysis of the readings. The software then suggests how the three equalizers (represented as dials on the back panel of the subwoofer) should be set for optimum performance.

The only known “automated’ equalization system can be found on certain full-range Bose Home Entertainment systems. The Bose ADAPTiQ system automatically adapts a music system. A user dons a headset that includes microphones. The headset records output from the system. The output is analyzed and then optimally adapted. However, AdaptiQ does not allow the user to view the output of the speakers and to adjust according to the user's listening desires.

### SUMMARY OF THE INVENTION

The present invention comprises systems and methods for optimizing speaker location and speaker sound processing. An example system includes a self-contained speaker unit that includes a speaker, an amplifier coupled to the speaker, and a processor coupled to the amplifier. The processor receives a sound signal from an external source and a sound signal from a microphone, processes the sound signal from the external source based on a plurality of parameters, and generates a video signal based on the sound signal received by the microphone. The processor outputs the processed sound signal to the speaker via the amplifier.

The system includes a control device, such as a wireless remote control, that allows a user to manipulate the parameters.

The processor generates a test sound signal that is outputted to a receiver that is coupled to the system. The receiver receives and processes the test sound signal, returns the processed test sound signal to the processor and sends the processed signal to the speakers coupled to the receiver. The received test sound signal is processed by the processor and outputted to the speaker via the amplifier.

In accordance with other preferred aspects of the invention, the generated video signal includes a graphical user interface. The graphical user interface includes a frequency response graph of the sound signal received by the microphone. In addition, the graphical user interface includes an eight band equalizer.

In accordance with still further preferred aspects of the invention, each of the eight bands of the equalizer is switchable between a graphic and a parametric equalizer.

In accordance with yet other preferred aspects of the invention, the graphical user interface includes a parameters section for changing the parameters using the control device. The parameters include low pass crossover frequency, low pass crossover slope, subsonic frequency, subsonic slope, phase, polarity, volume, contour frequency, contour level, and servo lop gain, which in turn affects the amount of distortion the speaker produces.

In accordance with still another preferred aspect of the invention, a speaker system includes a speaker, a processor coupled to the speaker, and an accelerometer system. The accelerometer system includes an accelerometer mechanically coupled with the speaker. The accelerometer generates an analog motion signal based on sensed motion of the speaker. The accelerometer system also includes an analog to digital converter coupled to the accelerometer and the processor. The analog to digital converter converts the analog motion signal to a digital signal and send it to the processor. The processor receives a sound signal from an external source and sends the received sound signal to the speaker. The processor compares the received sound signal to the received digital motion signal to determine a sound processing value. The processor adjusts a received sound signal based on the determined sound processing value.

### BRIEF DESCRIPTION OF THE DRAWINGS

The preferred and alternative embodiments of the present invention are described in detail below with reference to the following drawings.

FIG. 1A is a block diagram of a system formed in accordance with the present invention;

FIG. 1B is a perspective view of room that includes a portion of the system components shown in FIG. 1A;

FIG. 2 is a front view of a speaker interface panel formed in accordance with the present invention;

FIG. 3 is a front view of a remote control device that interacts with the system;

FIGS. 4 and 5 are screen shots of graphical user interfaces outputted by the speaker system on a display device;

FIG. 6 is a flow diagram of a process performed by the system shown in FIG. 1A;

FIGS. 7-11 are screen shots of the user interface at different stages of the process shown in FIG. 6.

FIG. 12 is a block diagram of an alternate embodiment of the present invention;

FIG. 13 is a frequency response graph of the speakers within the speaker system shown in FIG. 12; and

FIG. 14 is a block diagram of another alternate embodiment of the present invention.

### DETAILED DESCRIPTION OF THE PREFERRED EMBODIMENT

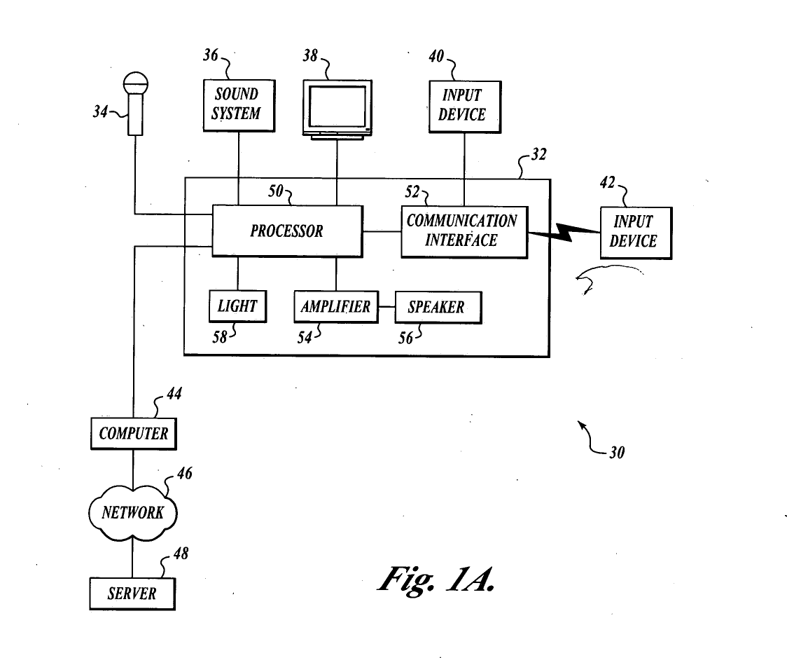

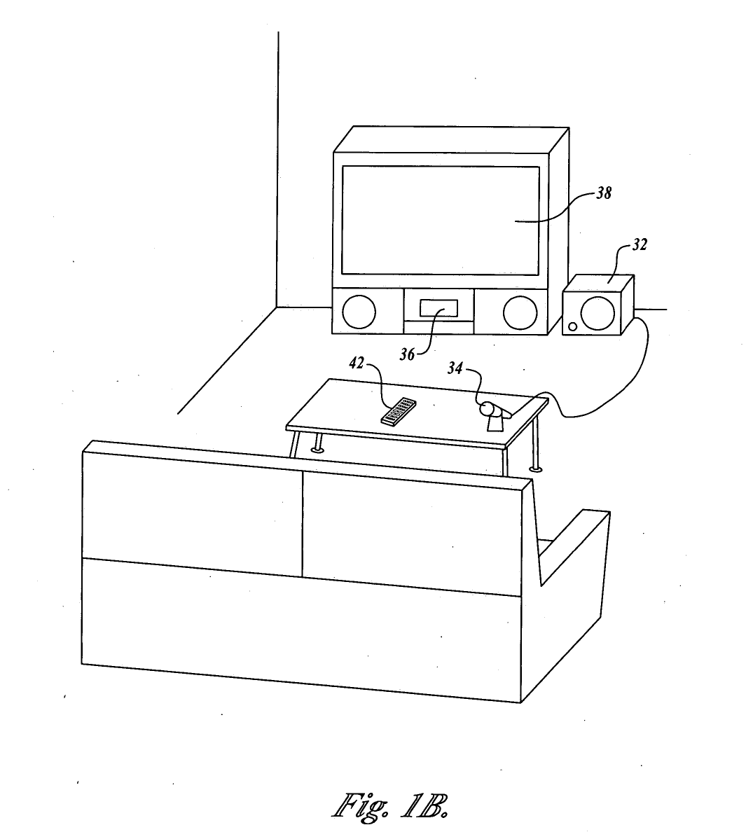

FIGS. 1A and 1B illustrate an exemplary speaker system 30 that easily allows the user to place a speaker optimally within a room as well as control other speaker related functions. In one embodiment, the system 30 includes a speaker unit 32 that is operatively coupled with a microphone 34, a sound system 36, and a display 38, (such as a television). The speaker system 30 also includes a wireless input device 42 for interacting with the speaker unit 32. The speaker unit 32 may also be coupled to a wired input device 40, and to a computer system 44 and can communicate with a universal remote control device, such as that produced by Crestron.

In one embodiment, the speaker unit 32 includes a processor 50, a communication interface 52, an amplifier 54, a speaker 56, and a light 58, all included within an acoustically designed speaker housing (not shown). The processor 50 is operatively coupled to the communication interface 52, the amplifier 54, the speaker 56, and the light 58. The processor 50 is also coupled to the microphone 34, the sound system 36, the display 38, and the computer system 44. The communication interface 52 includes a wire connection to the wired input device 40 and a component for wirelessly communicating with the user input device 42.

In one embodiment, the wireless input device 42 is a remote control device, such as an infrared/optical or RF remote control, that sends control signals to the processor 50 via the communication interface 52. The processor 50 or the communication interface 52 converts the received control signals into digital format for processing.

In one embodiment, the computer system 44 is coupled to a public or private data network 46. A server 48 is also coupled to the network 46. The server 48 includes software updates for the processor 50 of the speaker unit 32. When software updates are available at the server 48, a user at the computer system 44 retrieves the software updates via the network 46. After retrieval of the software updates, the computer system 44 downloads the software updates into the processor 50. The processor 50 includes an associated memory for storing an application program that performs the process described below.

An example of the amplifier 54 used in the speaker unit 32 is a switching-type amplifier, such as that described in co-owned U.S. Pat. No. 5,963,086, which is herein incorporated by reference. An example of the microphone 34 is any commercially available microphone, such as microphone model 797 made by Beijing Electronics.

The system 30 allows a user to locate the speaker unit 32 or groups of speaker units 32 in any location within a room. The processor 50 produces and sends to the sound system 34 a test sound signal. The sound system 36 receives the test sound signal through, for example, an auxiliary input jack so that it may process the test sound signal as with any other input sound signal. When the particular speaker embodiment is a subwoofer, the test signal is preferably a sweep signal within a typical subwoofer frequency range of about 15 Hz to about 200 Hz. The sound system 36 processes and outputs the processed test sound signal to the sound system speakers and to the speaker 56 via the processor 50. Note that in a preferred embodiment the speaker 56 is a subwoofer. In such an embodiment, additional higher frequency range speakers would also be used with the system. The additional speakers are not illustrated in FIGS. 1A or B, but would be in signal communication with the sound system 36 if used.

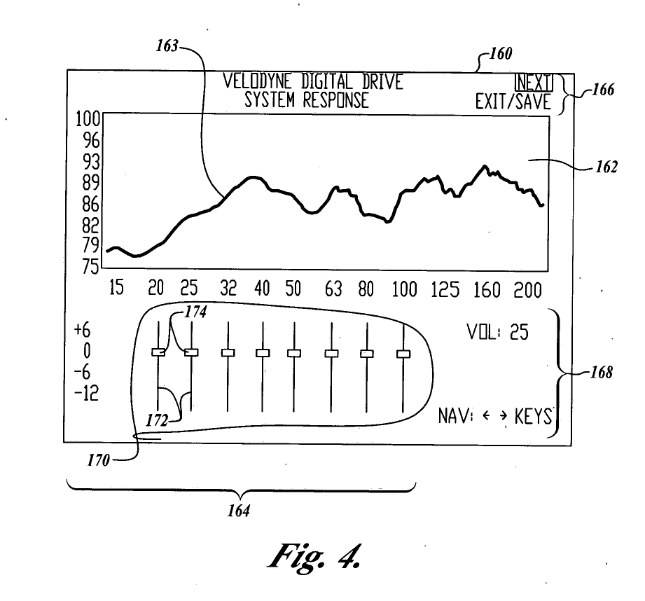

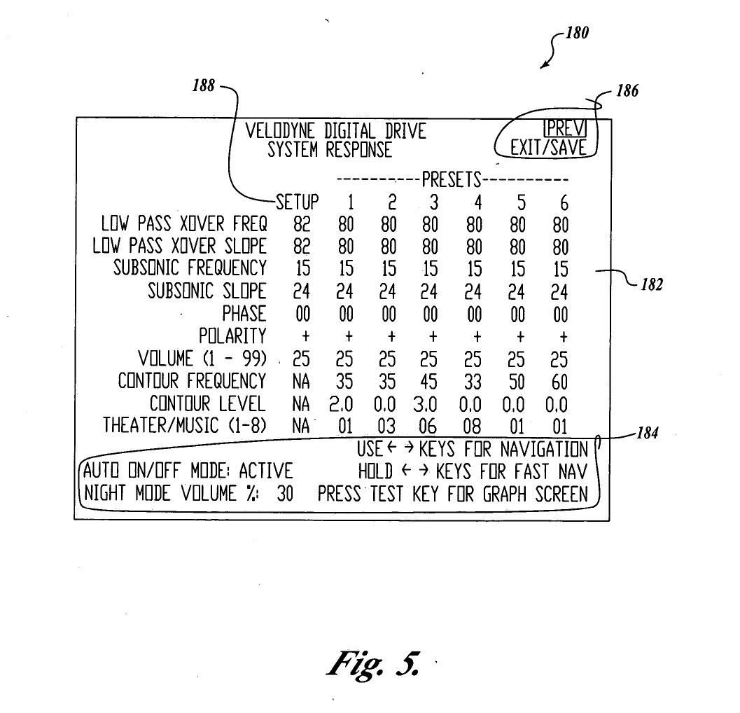

The microphone 34 receives the test signal after it is played on the speaker 56 and any other speakers that are reproducing the test signal. The signals received by the microphone, in turn, are passed directly to the processor 50 or to the processor 50 via the systems 36 or 44. The processor 50 produces a video signal indicating the frequency response of the test sound signals produced by all speakers and received by the microphone 34 and digitized within the processor 50. The video signal is presented on the display 38. In order to optimize the system for a particular room, the microphone 34 is placed in a desired listening location. With the microphone 34 in a desired listening location, the user moves the speaker unit 32 in order to get a desired frequency response of the sound that is outputted by the speaker 56. In order to determine the desired location of the speaker unit 32, the displayed frequency response is optimized thus indicating optimum speaker location. The input devices 40 and 42 allow a user to adjust other variables associated with the amplifier 54 and the speaker 56. A graphical user interface presented on the display 38 that illustrates the frequency response and other speaker variables are shown and described in more detail below with regards to FIGS. 4 and 5. The graphic equalizer enables the sound to be further tailored, or to optimize the sound quality to a particular listening location and/or additional speakers in the system without moving the speaker 56.

The user may desire not to move the speaker 56, because they prefer a specific location in a room. If this is the case, the user will optimize performance of the speaker 56 by controlling various speaker settings that will be described in more detail below.

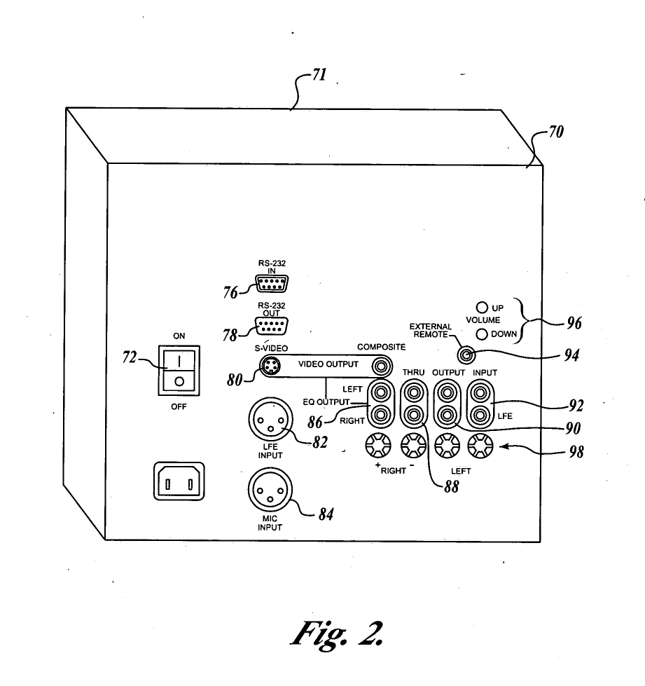

As shown in FIG. 2, a speaker interface panel 70 is mounted to a back surface of a housing 71 of the speaker unit 32. The panel 70 includes a power switch 72, and a data IN-port 76 that allows communication between the processor 50, and the computer system 44, a touch panel remote control, or another speaker unit 32. A data OUT-port 78 allows communication with another, speaker unit 32. In one embodiment the data ports 76 and 78 conform to the RS-232 communication protocol. A 12V trigger turns all the components in the system on and off together. A video port 80 is provided for wired connection to the display 38. An example of the video port 80 is an S-video port. A Low Frequency Extension (LFE) INPUT-port 82 receives a balanced LFE signal from the sound system 36 or the computer system 44. The LFE INPUT-port 82 is an XLR INPUT JACK (balanced input) that provides a grounded way to provide input signal to the woofer and is considered an alternate to RCA plugs. Three kinds of input signal are support—LFE (RCA left and right jacks) 92, XLR 82, and speaker level 98 (i.e. speaker wires from the amplifier of the sound system 36). A MIC INPUT-port 84 receives a microphone jack. EQ OUTPUT LEFT/RIGHT ports 86 outputs the test sound signal to the sound system 36. The THRU ports 88 share the input signal from the sound system to other speaker units 32. The THRU ports 88 are RCA plugs. Output ports 90 are RCA plugs that connect to the sound system 36 to provide a signal without bass to be played by the main speakers. INPUT LFE ports 92 are RCA connections that receive the signal from the sound system 36 like the LFE INPUT-port 82. A REMOTE SENSOR port 94 receives a jack associated with the wired input device 40. VOLUME UP/DOWN buttons 96 when depressed incrementally raise or lower the speaker's volume. SPEAKER LEVEL INPUT RIGHT/LEFT ports 98 allow either banana plug/jack or exposed wire/terminal connections.

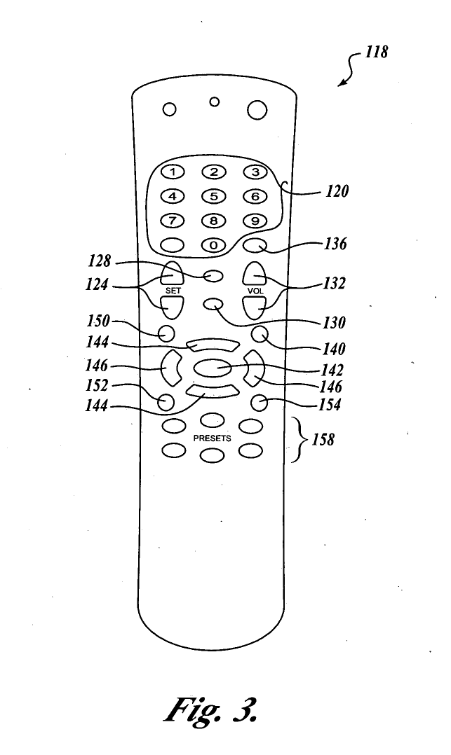

An example of the wireless input device 42 is shown in FIG. 3. The device 42 includes a numeric keypad 120 for entering numbers with respect to a graphical user interface (GUI) that is displayed on the display device 38. The remote device 42 sends IR, RF, or other wireless signals to the communication interface 52. Stored programming instructions within the communication interface or the processor interpret the signals and cause the processor to perform the function associated with the command.

A pair of ± SET buttons 124 increase (+) or decrease (−) a value in a specified field in the displayed GUI. A LIGHT button 128 turns the speaker's light 58 on or off. When activated a NIGHT button 130 limits the output of the speaker 56 and illuminates the light 58 in an amber mode to signify that the speaker unit 32 is in night mode. VOL buttons 132 raise or lower the volume of the speaker unit 32. A MUTE button 136 mutes the sound sent to the speaker 56. An EXIT button 140 exits a SETUP mode of the application program executed by the processor 50. A SELECT button 142 toggles values within a selected field in the displayed GUI. Above and below the SELECT button 142 are up and down arrow buttons 144 and adjacent to the SELECT button 142 are left and right arrow buttons 146. The buttons 144 and 146 control a cursor or highlight/select device that is presented on the GUI.

A TEST button 150 when depressed activates a TEST mode of the application program. In the TEST mode, the test sound signal is generated and output through the speakers. A RESET button 152 restores previously stored values. A MENU button 154 enters a SETUP mode of the application program. PRESET buttons (1-6) 158 access five equalizer presets and one equalizer-defeat listening preset. An EQ DEFEAT present when selected disables the equalizer, thereby demonstrating the benefit of the equalizer.

FIG. 4 illustrates a screen shot of a GUI page 160 that is generated by the processor 50 and presented on the display 38. The GUI page 160 includes'a graph area 162, an equalizer area 164 located below the graph area 162, a function area 166 located above the graph area 162, and a description area 168 located adjacent to the equalizer area 164. The graph area 162 presents a graph 163 of a frequency response of the signals received by the microphone 34.

In one embodiment, the speaker 56 is a subwoofer designed to operate within a range of approximately 15 Hz to 120 Hz. The presented graph 163 has an x-axis starting at 15 Hz and ending at approximately 200 Hz and a y-axis ranging from approximately 60 dB to 100 dB. In this embodiment, the presented graph 163 illustrates the frequencies of the signal received by the microphone within the range of 15 Hz to about 200 Hz, with the subwoofer producing the lowest frequency portion (15 Hz-125 Hz) and additional speakers associated with the sound system producing frequencies between 125 and 200 Hz.

The equalizer area 164 includes an equalizer GUI 170 that includes 8 vertical equalizer bars 172. Each bar 172 of the equalizer GUI 170 includes a graphically slideable knob 174. Each equalizer bar 172 is associated with a frequency on the x-axis of the graph 163 that is directly above the equalizer bar 172. For example, the equalizer bar 172 that is below 20 Hz on the x-axis of the graph 163 correlates to 20 Hz.

The functions area 166 includes selectable functions that allow the user to switch to another GUI page, such as that shown in FIG. 5 below, save any changes, or exit the GUIs.

The information area 168 provides additional information about the user's interaction with the GUI page 160. An example of the information presented in the information area 168 is described in more detail below.

FIG. 5 illustrates a screen shot of a second GUI page 180 that is produced by the processor 50 and presented on the display 38. As with the first GUI page, the information on the second GUI page is stored in a memory associated with the processor. The GUI page 180 includes a preset area 182, an information area 184 located below the preset area 182, and a functions area 186 located above the preset area 182. Adjacent to the preset area 182 is a setup column 188 that allows a user to adjust certain variables included within all of the presets. The preset area 182 includes 6 speaker presets. The presets are selected by activating the corresponding numbered preset button 158. Each preset can be individually adjusted if desired. The presets are as follows as labeled on the input device 42: 1. Action/Adventure; 2. Movies; 3. Pop/Rock; 4. Jazz/Classical; 5. Custom; 6. EQ Defeat. The characteristics of each of the presets are defined by the settings (FIG. 5) that are optimized based on the type of music that is received.

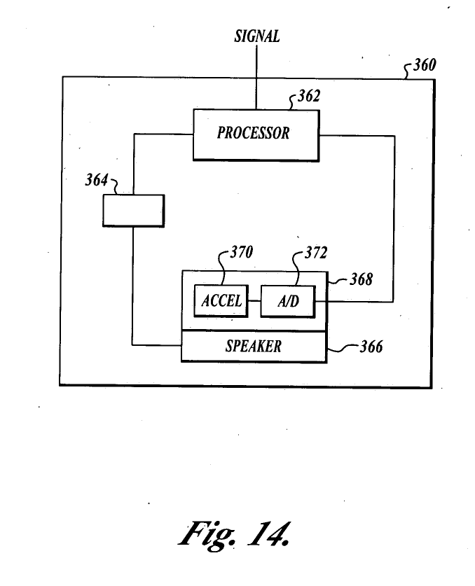

The six presets include the following editable fields:
Low Pass Crossover Frequency and Slope—Adjusts the upper limit of the subwoofer's frequency response. Select a crossover setting, in increments of 1, between 15 Hz and 199 Hz and slope at 6, 12, 18, 24, 30, 36, 42 and 48 dB/octave.
Subsonic Filter Frequency and Slope—Sets the subwoofer's subsonic filter (low frequency limit), in increments of 1, between 15 Hz-199 Hz and slope at 6, 12, 18, 24, and 48 dB/octave.
Phase—Sets the phase (delay) of the subwoofer's output signal, 0 to 180 degrees (adjustable in 15 degree increments).
Polarity—Sets the subwoofer's polarity by toggling between positive (+) or negative (−) by reversing the phase 180 degrees.
Volume—Sets the subwoofer's volume in increments of 1, between 0-99. This sets the preset's volume different from the volume of the subwoofer. So, if a user found during setup that 7 was a good setup volume for the subwoofer, then preset 1 would increase the sub's volume according to the value set in this area. Using the VOL + or VOL − buttons 132 on the remote the speak unit volume and the preset volume are adjusted together.
Contour Frequency—Sets a frequency to boost or cut the signal to the subwoofer in response to specific types of source material.
Contour Level—Sets the amount of boost or cut at the frequency specified in the contour frequency. Contour frequency and level settings act as an additional equalizer that can be used to manipulate the frequency contour of the subwoofer when this particular preset is invoked.
Theater/Music Indicator—Sets the distortion limiting capabilities of the digital servo system and allows a choice between a “theatrical” subwoofer, a “musical” subwoofer, or somewhere in-between. The digital servo system is described in more detail below with respect to FIG. 14. The “musical” setting represents maximum gain from the servo, and thus the least amount of distortion possible from the subwoofer. The theatrical setting relaxes the servo a bit to allow a bit more distortion to enter the playback, making an overall louder and more impressive sub for explosions and other theatrical content. The scale is 1 for maximum theater (least amount of servo gain) and 8 for maximum music (most amount of servo gain). The “setup” values cascade to the individual values for the presets. The individual values for each preset can be separately changed if desired.

The information area 184 includes the following controls:
Auto On/Off Active/Inactive—When active is indicated, the subwoofer is automatically shut off after a length of time without any source signal (i.e. signal from external source). When inactive is indicated, the woofer automatically wakes upon receiving input signal.
Night Mode Maximum Volume—When the NIGHT button 130 is activated on the input device 42, the night mode is invoked. Night mode is indicated by illumination of the amber bar (light 58) located on the front of the speaker unit 36.

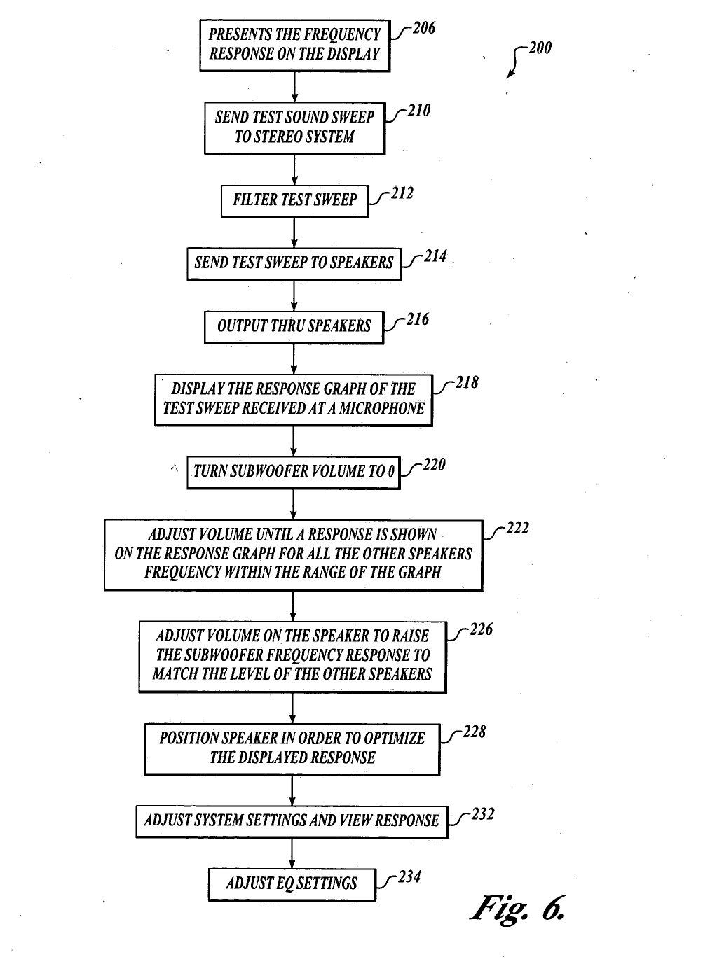

FIG. 6 illustrates an exemplary process 200 for using the system 30 in order to activate and optimize room location for the speaker 56. First, at block 206, the processor 50 presents a frequency response graph of sound received by the microphone 34 on the display. At block 210, the processor 50 sends a test sweep sound signal to the sound system 36 or the computer system 44, depending on which one is being used as a receiver. As another alternative, the test sweep signal can be sent directly from the processor 50 to the speaker 56, without first passing through a computer or sound system. Next, at block 212, the sound system 36 or the computer system 44 filters the test sweep signal in accordance with normal filtering procedures. Normal filtering procedures include filtering a received music or sound signal according to which speaker is to receive the signal. For example, if the speaker 56 is a subwoofer designed to play frequencies below 120 Hz, frequencies above 120 Hz are typically filtered out before the signal is sent to the subwoofer. At block 214, the filtered test sweep signal is sent to the speakers coupled to the sound system 36 (or optionally speakers coupled to the computer system 44(not shown)) and to the speaker unit 32.

The respective speakers output the received test sweep signal as sound, see block 216. The test sweep signal is a constant magnitude signal that starts at 15 Hz and ends at 200 Hz and repeats. Other test signals may be used, sweeping from high to low frequencies, for example. At block 218, the processor 50 receives a sound signal generated by the microphone 34, digitizes the received sound signal, processes the digitized signal to determine the frequency response pattern, and presents a frequency response graph on the display based on the determined frequency response pattern. Next, at block 220, the user turns the subwoofer volume down to 0 either by the volume control buttons 132 on the remote 42 or the volume control buttons 96 on the panel 70. At block 222, the user adjusts the volume on the speaker system or the computer system 44 until the displayed frequency response for the frequencies associated with the speakers of the sound system 36 or the computer system 44are all shown within the dB range (y-axis) of the displayed frequency response graph. Next, at block 226, the user adjusts the volume of the subwoofer 56 in order to raise the associated frequencies displayed on the frequency response graph to a level that best visually matches the level of the frequencies of the other speakers. At block 228, the user positions the speaker 56 within a room in order to generate an optimal frequency response as presented on the frequency response graph. The optimum frequency response is preferably a flat response across the range of frequencies for the speaker.

At block 232, the user adjusts the speaker settings as shown in the FIG. 5 and selects a test mode (test buttons 150) that allows the user to view the frequency response at the present settings. Next, at block 234, the user adjusts the settings of the displayed graphic equalizer 170 to further optimize the displayed frequency response. For example, when unwanted peaks occur in the displayed frequency response graph, the slideable button 174 is lowered, thereby decreasing output at the associated frequency. When unwanted valleys 174 occur in the displayed frequency response graph, the slideable button 174 on the associated frequency bar 172 is increased for increasing the output of the speaker 56 at that frequency, thereby removing the valley.

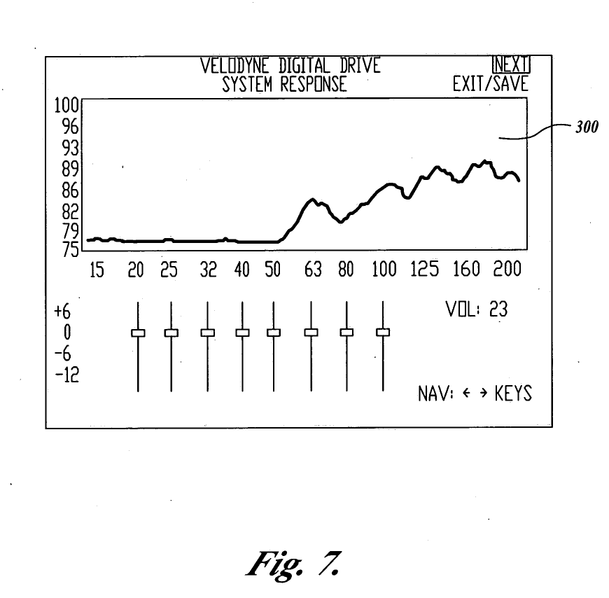

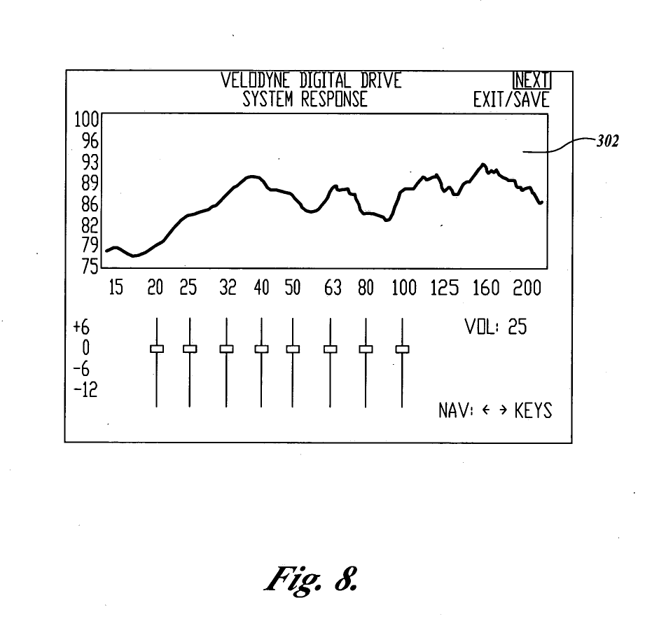

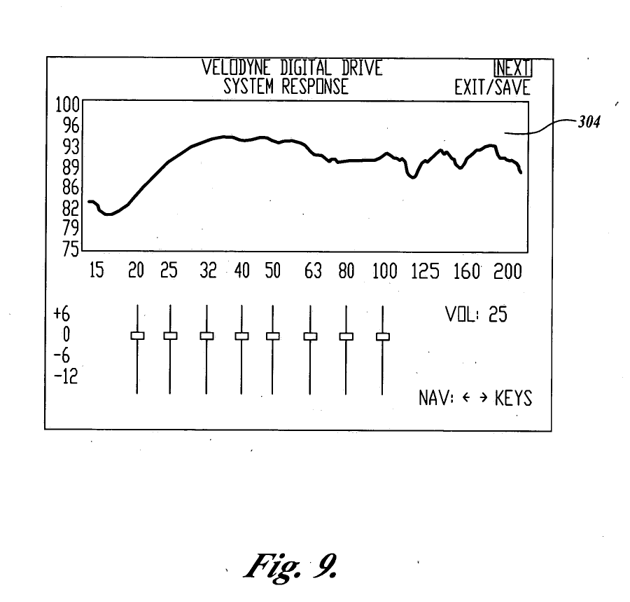

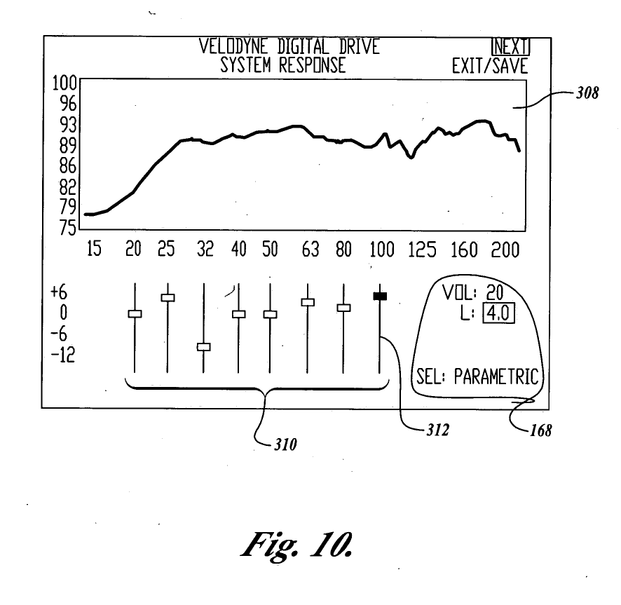

FIG. 7 illustrates a frequency response graph 300 that is presented after the adjustment of the volume has occurred (block 222). FIG. 8 illustrates a frequency response graph 302 after the volume of the subwoofer has been raised (block 226). FIG. 9 illustrates a frequency response graph 304 that is presented on the display after the speaker has been moved to an optimum location within the room (block 228). FIG. 10 illustrates a frequency response graph 308 after the user has adjusted certain system settings and adjusted the displayed equalizer 310 (block 234). The optimum frequency response graph 308 would be shown as a flat line at the dB level that corresponds closely to what is outputted by the speaker 56. The information area 168 presents the volume level for the subwoofer and a value for a frequency bar 312 selected in the displayed equalizer 310. A frequency bar 312 is selected by activating one of the buttons 146 until the desired frequency bar 312 is highlighted. The knob on a highlighted is moved up or down on the frequency bar 312 by activating the respective button 144. Also, the information area 168 indicates that if the user activates the select button 142 on the remote control 118, then the processor 50 enters a parametric equalizer mode as shown and described with regards to FIG. 1.

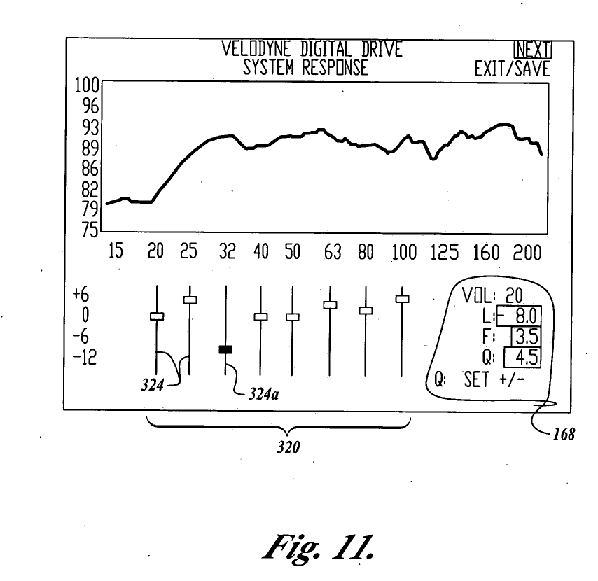

FIG. 11 illustrates a parametric equalizer mode of the application program. A parametric equalizer 320 includes equalizer bars 324 that may be adjusted to any of an infinite number of frequency settings within a preset range of frequencies. In this example, the user has selected the frequency bar 324a that was previously at 32 Hz, and moved the frequency bar to the frequency value 35 Hz as indicated in the information area 168. Movement of the frequency bars 324 is performed by first selecting the bar using the arrow buttons 146, selecting the parametric mode, and then using left and right arrow buttons 146 to move the frequency bar 324 in the desired direction. The set buttons 124 allow a user to increase or decrease the Q setting of the respective frequency bar. The Q setting is “width” of the equalizer that is being set. The higher the Q value, the more focused the effect of the equalizer in terms of frequency range. A very low Q covers a wide range and causes a radial sloping change, a very high Q causes a needlepoint correction in the curve.

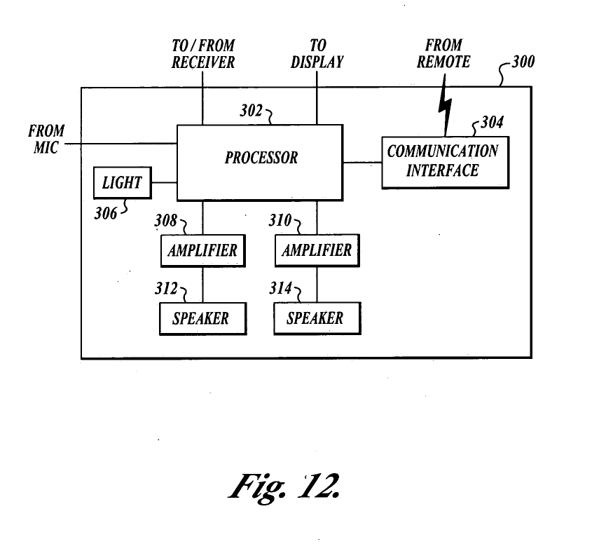

FIG. 12 illustrates a multispeaker unit 300 that is configured similarly to that of speaker unit 32 (FIG. 1), except that multiple speakers are provided. The multispeaker unit 300 includes a processor 302, a communication interface 304, an indicator light 306, a first amplifier 308, a second amplifier 310, a first speaker 312, and a second speaker 314. The speakers 312 and 314 are preferably of different sizes in order to output a range of frequencies that the speaker unit 300 is designed to output. For example, one of the speakers is an 18-inch subwoofer speaker and the other is a 12-inch subwoofer speaker. The components of the multispeaker unit 300 are included in a container, similar to the housing 71 of speaker unit 32

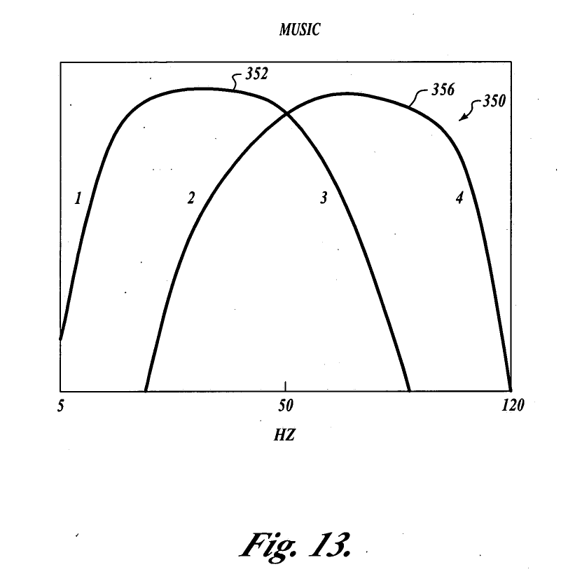

FIG. 13 illustrates exemplary frequency response 350 of the speakers 312 and 314 of the unit 300. The frequency response 350 includes an 18-inch subwoofer response 352 and a 12-inch subwoofer response 356. The rising edge of the 18-inch subwoofer response 352 is the subsonic filter setting that the user enters via the GUI page 180 (FIG. 5). The trailing edge of the 12-inch subwoofer frequency response 356 is the low-pass crossover frequency that is also set in the settings GUI page 180. The leading edge of the 12-inch subwoofer frequency response 356 and the trailing edge of the 18-inch subwoofer frequency response 352 are not adjustable by the user. The processor 302 sets the values of the leading edge of the 12-inch subwoofer frequency response 356 and the trailing edge of the 18-inch subwoofer frequency response 352 automatically to provide the best overall response of both speakers for covering the frequency range of 15 to 120 Hz.

In one embodiment, the processors 50 or 302 use pulse width modulation (PWM) output channels (not shown) for generating a two color video signal. One PWM channel produces a video horizontal blanking signal. Two other PWM channels produce a color burst frequency of 3.579545 Mhz and one gates the burst frequency. Another pair of PWM channels generates a phase signal and gates blue on and off for the background of the video. The video produced by the PWM output channels is delayed and serially clocked for producing a black edge around each white character. A clock of the processors 50 or 302 (digital signal processors—DSP) is a multiple of standard burst frequency (3.579545 Mhz), thus, the processors 50 or 302 run at 42.95454 Mhz or 12 times the burst frequency.

FIG. 14 illustrates an alternate embodiment of the present invention. A speaker unit 360 includes a processor 362, one or more amplifiers 364 coupled to one or more speakers 366, and an accelerometer unit 368 attached to each speaker 366. The accelerator unit 368 includes an accelerometer 370 and an analog to digital (A to D) converter 372. The processor 362 converts received music signals to digital, processes the digital signals according to internal equalizer or other; settings, and sends the processed signals to the amplifier 364. The amplifier 364 powers the speaker 366 according to the received signal. The accelerator 370 senses the motion of the speaker or motion of the speaker unit 360 which is a box (not shown) in which the speaker 366 is mounted. The A to D converter 372 converts signals from the accelerator 370 into digital format and sends the digital signal to the processor 362. The processor 362 compares the previously received music signal to the digitized accelerometer signal and determines whether the accelerometer 370 detected a motion that corresponds to what was expected based on the received music signal. If the processor 362 determines by the comparison that the accelerometer signal differs from the received music signal, then the processor 362 adjusts processing of the signals that are sent to the speaker 366. Co-owned U.S. Pat. No. 4,573,189 describes a loud speaker with high frequency motional feedback and is hereby incorporated by reference. Because the preferred embodiment performs the adjustments in digital form; adjustments of the received music signal are performed three times faster than previously done in analog.

In one embodiment, the processor 362 does not perform processing adjustments of the received music signal if it determines that the received music signal is below a threshold volume level. If it is below the threshold volume level, the processor 362 does not listen to signals from the accelerometer unit 368.

In a preferred embodiment, the invention employs a single, general purpose DSP processor to perform the audio and video functions, such as a Texas Instruments TMS320LF2407 type. An external Codec is used to digitize the incoming signal. While the part employed, a Texas Instruments PCM3003, has both a left and a right channel, the incoming audio signals are summed externally and the unused channel is employed as a low-gain alternative input, to extend the dynamic range of the input. The output portion of the Codec is used to output the sweep tone audio signal.

An embodiment of the invention employs numerous pulse width modulation (PWM) output drivers that are part of the standard DSP. The PWM drivers generate the video signal. While these PWM drives are usually used for motor control applications, they are also employed to produce a low cost video out of the two color variety, in this case the colors being white letters on a blue background. One PWM channel is set to produce the horizontal blanking signal. Summed into this is the color burst, which is derived by another two PWM channels, one to generate the burst frequency, of 3.579545 Hz, which runs continuously, and another to gate the burst at the proper time. Another pair of PWM output drivers includes a driver to generate the proper phase relative to the burst, and another to gate the blue on and off generates the blue background. The synchronous serial port generates the video information. Additionally, the video information is fed through a delay stage, including a pair of flip-flops. The serial out clock gates these. The purpose of this is to enable a black edge around each white character. Otherwise, the white characters will have color artifacts at their edges. Shutting off the blue whenever there is a character anywhere in the delay line does this. The video information is taken from the center of the delay line, so the black appears at each edge. The clock for the DSP is a multiple of the standard burst frequency (3.579545 Mhz.) In this case, the DSP runs at 42.95454 Mhz, or 12× the burst frequency.

Because of the requirements of minimal signal delay from the DSP to the amplifier, and the need for line voltage isolation, a transformer coupled PWM drive is employed to convey the digital signal to an analog form that can be used by the amplifier. However, the DSP, as only having a 23 nanosecond cycle time, provides too course of a PWM output to be useful. Therefore, two PWM outputs are used, one having a full-scale range just equal to a single bit increment of the main output. Thus, the resolution in hits is effectively doubled from that obtainable with a single output. The two PWM signals are combined and lowpass filtered before being sent to the amplifier. While the low-pass filters technically add phase delay to the signal, this can be corrected for in the DSP and hence there is a negligible system delay in issuing the signal to the amplifier.

The preferred embodiment uses a tandem voice coil arrangement employing two separate magnetic fields, although only one magnet is used. The magnetic field circulates from the magnet, across the top gap, then down the pole piece, then across the lower gap and then back to the magnet. A special non-magnetic element, which we call a yoke, is utilized to position the pole piece within the two gaps. Two separate coils arc used, although they arc wound on the same former. Since the direction of the magnetic field is opposite on the bottom with regards to the top field, it is necessary to reverse the winding direction on the two coils. This can be done by employing separate leads to each coil, or in the preferred embodiment, by reversing the direction of the winding during the winding process. This type of coil has several benefits when used in this system.

The two coils have twice the surface area as an equivalent single coil. Therefore, they dissipate heat much better than a single coil. Also, the flow-through design of the pole piece arrangement allows more cooling air around the coils. Also, the use of two spiders, one above and one below, serve to support the voice coil from rubbing without the usual requirement of the surround performing that function.

The DSP also has an asynchronous serial port that is, used in the preferred embodiment for several purposes. It allows a general-purpose controller, such as those made by Crestron and others, to command the processor to adjust settings to the user's taste such as speaker volume and preset.

Feedback is provided back to the DSP from the amplifier in the form of a clipping detection circuit. Since the amplifier's output before clipping varies as the load and line voltage sag, it is useful to know how close the amplifier is to the level at which clipping occurs. This information must be sent across the isolation barrier. The preferred embodiment has a simple and effective way of accomplishing this. Rather than knowing the output levels directly, just the remaining headroom is transmitted. This is done using an inexpensive, uncalibrated dual optocoupler, a MCT-6. Each optocoupler drive is connected to the difference between the amplifier output and each rail voltage. Therefore, when the amp is in clipping, one LED will be off while the other is at a relative maximum. It is the LED that is off that is of interest to the DSP as an indicator of clipping. Since the optocoupler is uncalibrated, the “off state is universal and all optocouplers behave similarly. There is an initial calibration a startup that determines their relative range of the optocoupler. The receiving end of the optocoupler is connected to two of the DSP's analog to digital inputs, using simple resistor pull-ups.

The light is a two-color EL type. Blinking of the logo light is used as a feedback to the user during remote command inputs and during programming updates, when no video is available. The preferred embodiment also includes a 12V trigger input, useful for linking an entire audio-video system to turn on and off with a simple, hardware solution. The preferred embodiment also includes a simple, passive high pass crossover out; useful for removing some of the deep bass from the users satellite speakers. The RS-232 port is also used to communicate with a remote, digital high pass crossover.

The accelerometer is used in a negative feedback arrangement, thus, the signal delay is kept as low as possible, in order to control phase error into the signal loop, which in turn limits the amount of feedback gain possible. A sampling type A-D converter is used in the accelerometer, in this case a Texas Instruments ADS8325, 16-Bit, 100kSPS Serial Out, 2.7V to 5.5V Micro Power Sampling ADC.

Appendix A includes figures of an exemplary single speaker unit and associated circuitry. Appendix B includes figures of an exemplary dual speaker unit and associated circuitry.

While the preferred embodiment of the invention has been illustrated and described, as noted above, many changes can be made without departing from the spirit and scope of the invention. For example, the steps in the process 200 can be altered and the components in the systems of FIGS. 1, 12, and 14 can be altered. Accordingly, the scope of the invention is not limited by the disclosure of the preferred embodiment. Instead, the invention should be determined entirely by reference to the claims that follow.

1. A speaker apparatus comprising:
at least one speaker;
a processor coupled to the at least one speaker, the processor comprising:
a first component configured to receive a sound signal from an external source; and
a second component configured to generate a video signal based on the sound signal; and
a video output port coupled to the second component.

2. The apparatus of claim 1, wherein the external source is a receiver and the sound signal comprises a portion received by a microphone.

3. The apparatus of claim 2, wherein the processor further comprises:
a third component configured to process a portion of the sound signal based on a plurality of parameters; and
a fourth component configured to output the processed signal to the at least one speaker.

4. The apparatus of claim 1, wherein the external source is a microphone.

5. The apparatus of claim 4, wherein the processor further comprises:
a third component configured to receive a second sound signal from a second external source;
a fourth component configured to process the second sound signal based on a plurality of parameters; and
a fifth component configured to output the processed second sound signal to the at least one speaker.

6. The apparatus of claim 5, further comprising a control device configured to allow user manipulation of the parameters.

7. The apparatus of claim 5, further comprising a wireless communication component coupled to the processor, wherein the control device is a wireless remote control.

8. The apparatus of claim 7, wherein the wireless communication component is an optical sensor.

9. The apparatus of claim 5, wherein the processor further comprises:
a sixth component configured to generate a test sound signal.

10. The apparatus of claim 9, further comprising a port configured to output the test sound signal.

11. The apparatus of claim 5, wherein the processor further comprises:
a sixth component configured to receive changes to one or more of the first thru fifth components.

12. The apparatus of claim 1, further comprising a housing configured to include the at least one speaker and the processor.

13. The apparatus of claim 12, further comprising volume controls mounted to the housing and configured to control output of the at least one speaker.

14. The apparatus of claim 12, further comprising an indicator light coupled to the processor.

15. The apparatus of claim 1, further comprising:
at least one amplifier coupled to the at least one speaker.

16. A sound system including a receiver, the sound system comprising:
a display;
a microphone;
a control device; and
a speaker apparatus coupled to the display, the microphone, the control device, and the receiver, the speaker apparatus comprising:
at least one speaker; and
a processor coupled to the at least one speaker, the processor comprising:
a first component configured to receive a first sound signal from the receiver and a second sound signal received by the microphone;
a second component configured to process the first sound signal based on a plurality of parameters and output the processed sound signal to the at least one speaker; and
a third component configured to generate a video signal based on the second sound signal;
a fourth component configured to send the generated video signal to the display,
wherein the display presents the received video signal.

17. The system of claim 16, wherein the processor further comprises a fifth component configured to generate and send a test sound signal to the receiver.

18. The system of claim 17, wherein the receiver generates a sound signal based on the received test sound signal and sends the generated sound signal to the speaker apparatus for output to the at least one speaker.

19. The system of claim 18, wherein the generated a video signal includes a graphical user interface, the graphical user interface includes a frequency response graph of the sound signal received by the microphone.

20. The system of claim 19, wherein the graphical user interface further includes an eight band equalizer.

21. The system of claim 20, wherein the graphical user interface further includes a parameters section configured to allow a user to set at least a portion of the plurality of parameters using the control device.

22. The system of claim 21, wherein the portion of the plurality of parameters includes one or more of low pass crossover frequency, low pass crossover slope, subsonic frequency, subsonic slope, phase, polarity, volume, contour frequency, contour level, or a theatrical/musical performance parameter.

23. The system of claim 16, wherein the speaker apparatus further comprises a housing configured to include the at least one speaker and the processor.

24. The system of claim 23, wherein the speaker apparatus further comprises a port mounted on the housing, the port configured to receive the generated video signal from the processor.

25. The system of claim 23, wherein the speaker apparatus further comprises a port configured to receive sound signals from the processor.

26. The system of claim 23, wherein the speaker apparatus further comprises volume controls mounted to the housing and configured to control output of at least one speaker.

27. The system of claim 16, wherein the speaker apparatus further comprises a wireless communication component coupled to the processor, and wherein the control device is a wireless remote control.

28. The system of claim 27, wherein the wireless communication component is an optical sensor.

29. The system of claim 27, wherein the wireless remote control includes one or more preset buttons configured to send a preset command signal to the processor, wherein the processor processes sound signals according to parameters set in accordance with the received preset command signal.

30. A speaker apparatus comprising:
a first means for receiving a sound signal from an external source; and
a second means for generating a video signal based on the received sound signal.

31. The apparatus of claim 30, wherein the external source is a microphone.

32. The apparatus of claim 30, wherein the external source is a receiver and the sound signal comprises a portion received by a microphone coupled to the receiver.

33. The apparatus of claim 30, further comprising:
a third means for receiving a sound signal from an external source;
a fourth means for processing the sound signal from the external source based on a plurality of parameters.

34. The apparatus of claim 33, further comprising a fifth means for outputting the processed sound signal to at least one speaker.

35. The apparatus of claim 33, further comprising a fifth means for manipulating the plurality of parameters.

36. The apparatus of claim 35, further comprising a sixth means for converting wireless communication signal for use by the processor.

37. The apparatus of claim 33, further comprising a fifth means for generating a test sound signal.

38. The apparatus of claim 33, further comprising a fifth means for receiving and implementing changes to one or more of the second thru fourth means.

39. A method comprising:
receiving a first sound signal at a speaker unit from a source external to the speaker unit;
processing the first sound signal based on a plurality of parameters;
outputting the processed first sound signal to at least one speaker of the speaker unit;
receiving a second sound signal generated by a microphone at the speaker unit;
generating a video signal at the speaker unit based on the second sound signal; and
sending the generated video signal to a display coupled to the speaker unit.

40. The method of claim 39, further comprising:
generating a test sound signal at the speaker unit; and
sending the generated test sound signal to a sound system coupled to the speaker unit.

41. The method of claim 40, further comprising:
generating an output test sound signal at the sound system based on the received test sound signal; and
sending the generated output test sound signal to one or more speakers coupled to the sound system and to the at least one speaker of the speaker unit.

42. The method of claim 41, further comprising:
presenting the generated video signal on the display, wherein the presented video signal includes a graphical user interface, the graphical user interface includes a frequency response graph of the sound signal received by the microphone.

43. The method of claim 42, wherein the graphical user interface further includes an eight band equalizer.

44. The method of claim 43, wherein the graphical user interface further includes a parameters section configured to allow a user to set at least a portion of the plurality of parameters using the control device.

45. The method of claim 44, wherein the portion of the plurality of parameters includes one or more of low pass crossover frequency, low pass crossover slope, subsonic frequency, subsonic slope, phase, polarity, volume, contour frequency, contour level, or a theatrical/musical performance parameter.

46. A speaker apparatus comprising:
first and second speakers; and
a processor coupled to the first and second speakers, the processor comprising:
a first component configured to receive a first sound signal from an external source and a second sound signal from a microphone;
a second component configured to process the first sound signal based on a plurality of parameters; and
a third component configured to generate a video signal based on the second sound signal.

47. The apparatus of claim 46, wherein the first speaker is an 18 inch subwoofer and the second speaker is a 12 inch subwoofer.

48. The apparatus of claim 47, wherein the received first sound signal is between 0 Hz and 130 Hz and the second component automatically selects a first and second range of frequencies of the first sound signal and sends the first range of frequencies of the sound signal to the 18 inch subwoofer and sends the second range of frequencies of the first sound signal to the 12 inch subwoofer.

49. A method performed in a speaker apparatus, the method comprising:
receiving a first sound signal from an external source 0 Hz and 130 Hz and a second sound signal from a microphone, the first sound signal being between;
processing the first sound signal into a first and second range of frequencies based on a plurality of parameters;
sending the first range of frequencies of the sound signal to a first speaker;
sending the second range of frequencies of the first sound signal to a second speaker; and
generating a video signal based on the second sound signal,

50. The method of claim 49, wherein the first speaker is an 18 inch subwoofer and the second speaker is a 12 inch subwoofer.

51. A speaker apparatus comprising:
at least one speaker;
a processor having a memory configured to store program instructions to receive a sound signal from an external source, generate a video signal based on the sound signal, and output the generated video signal.

52. The apparatus of claim 51, wherein the external source is a receiver and the sound signal comprises a portion received by a microphone.

53. The apparatus of claim 52, wherein the program instructions further process a portion of the sound signal based on a plurality of parameters, and output the processed signal to the at least one speaker.

54. The apparatus of claim 51, wherein the external source is a microphone.

55. The apparatus of claim 54, wherein the program instructions further receive a second sound signal from a second external source, process the second sound signal based on a plurality of parameters, and output the processed second sound signal to the at least one speaker.

56. The apparatus of claim 55, further comprising a control device configured to allow user manipulation of the parameters.

57. The apparatus of claim 55, further comprising a wireless communication component coupled to the processor, wherein the control device is a wireless remote control.

58. The apparatus of claim 57, wherein the wireless communication component is an optical sensor.

59. The apparatus of claim 55, wherein the program instructions further generate a test sound signal.

60. The apparatus of claim 59, further comprising a port configured to output the test sound signal.

61. The apparatus of claim 55, wherein the program instructions further receive program instruction changes and execute the received changes.

62. The apparatus of claim 51, further comprising a housing configured to include the at least one speaker and the processor.

63. The apparatus of claim 62, further comprising volume controls mounted to the housing and configured to control output of the at least one speaker.

64. The apparatus of claim 62, further comprising an indicator light coupled to the processor.

65. The apparatus of claim 51, further comprising:
at least one amplifier coupled to the at least one speaker.

66. A speaker system comprising:
a speaker;
a processor coupled to the speaker;
an accelerometer system comprising:
an accelerometer being in mechanical communication with the speaker, the accelerometer being configured to generate an analog motion signal based on motion of the speaker; and
an analog to digital converter coupled to the accelerometer and the processor, the analog to digital converter being configured to convert the analog motion signal to digital.

67. The system of claim 66, wherein the processor comprises:
a first component configured to receive a sound signal from an external source and sending the received sound signal to the speaker;
a second component configured to receive the digital motion signal;
a third component configured to compare the received sound signal to the received digital motion signal;
a fourth component configured to determine a sound processing value based on the comparison; and
a fifth component configured to adjust a received sound signal based on the determined sound processing value.

68. Thee system of claim 67, wherein the processor further comprises:
a sixth component configured to disable the third and fourth component if the received digital motion signal is below a threshold value.

69. A method comprising:
receiving a sound signal from an external source;
sending the received sound signal to a speaker;
generating an analog motion signal;
converting the analog motion signal to digital;
receiving the digital motion signal;
comparing the received sound signal to the received digital motion signal;
determining a sound processing value based on the comparison; and
adjusting a received sound signal based on the determined sound processing value.

70. The method of claim 69, wherein comparing includes comparing the received sound signal to the received digital motion signal if the received digital motion signal is above a threshold value.

71. A system comprising:
a means for receiving a sound signal from an external source;
a means for sending the received sound signal to a speaker;
a means for generating an analog motion signal;
a means for converting the analog motion signal to digital;
a means for receiving the digital motion signal;
a means for comparing the received sound signal to the received digital motion signal;
a means for determining a sound processing value based on the comparison; and
a means for adjusting a received sound signal based on the determined sound processing value.

72. The method of claim 71, wherein the means for comparing compares the received sound signal to the received digital motion signal if the received digital motion signal is above a threshold value.
